(19) United States
(12) Patent Application Publication
(10) Pub. No.: US 2008/0251945 A1
(43) Pub. Date: Oct. 16, 2008

(54) Semiconductor package that has electronic component and its fabrication method

(75) Inventors: Chin-Te Chen, Taichung Hsien (TW); Kuo-Ching Tsai, Taichung Hsien (TW); Chung-Hsing Ko, Taichung Hsien (TW)

Correspondence Address: Edwards Angell Palmer & Dodge LLP, P.O. Box 55874, Boston, MA, 02205, US

(73) Assignee: Siliconware Precision Industries Co., Ltd., Taichung (TW)

(21) Appl. No.: 12/082,900

(22) Filed: Apr. 14, 2008

(30) Foreign Application Priority Data
Apr. 12, 2007 (TW) 096112809

(51) Int. Cl. H01L 23/52; H01L 21/44

(52) U.S. Cl. 257/779; 438/613; 257/E23.141; 257/E21.476

(57) ABSTRACT

A semiconductor device having at least an electronic component and its fabrication method are disclosed. The fabrication method comprises: applying a conductive material on each one of at least a paired solder pads arranged on a substrate by screen printing, with a recess formed in the conductive material on each one of the at least a paired solder pads, so as to expose a portion of each one of the at least a paired solder pads, wherein the recesses on the at least a paired solder pads are formed in position corresponding to each other; and mounting at least an electronic component having two opposing conductive terminals on the at least a paired solder pads, in a manner that the two opposing conductive terminals are introduced into the corresponding recesses of the conductive material so as for the electronic component to be electrically connected to the at least a paired solder pads via the conductive material by reflow. The recesses of the conductive material are capable of effectively securing the electronic component in position. Furthermore, both terminals of the electronic component are not formed with conductive material underneath so as to prevent the electronic components from tilting in level resulted from the uniform applying of the conductive material.

### BACKGROUND OF THE INVENTION

1. Field of the Invention

This invention generally relates to semiconductor devices having electronic components and fabrication methods thereof, and more specifically, to a semiconductor device having electronic components suitable for the application of the surface mounting technology and a fabrication method thereof.

2. Description of Related Art

Along with the improvement in integrated circuit fabrication technique, the development of electronic component design and fabrication is toward the trend of minimization, with larger scale and highly integrated circuits, therefore products of improved integrated circuits fabrication technology have more complete functions.

Under the foregoing circumstances, electronic components mounted by traditional through hole technology (THT) cannot be further minimized in size, therefore they take a great deal of space on an electronic carrier for carrying such electronic component. Furthermore, the through hole technology requires drilling holes in the electronic carrier for the pins of the electronic components to be inserted thereinto. As a matter of fact, the holes by the through hole technology are actually formed on both sides of the electronic carrier that undesirably consume a larger space on the electronic carrier. In addition, the solder joints used for electrically connecting the electronic components and the electronic carrier are volumnable due to the nature of such an electrical connection. Therefore, the surface mounting technology (SMT) has been developed and now widely used in the industry for mounting electronic components on electronic carriers without the aforementioned concerns in the through hole technology.

With the use of the surface mounting technology, the electrical connecting terminals (pins) of an electronic component are capable of being soldered onto the surface of an electronic carrier on which the electronic component is mounted. Therefore, as hole drilling of the electronic carrier is not required, the space on the electronic carrier will not be limited by the hole drilling and is thus capable of providing more freedom to the electronic component arrangement. Besides, since the electronic components suitable for surface mounting technology tend to be of a small size, the amount of electronic components available to be mounted on the electronic carrier is in higher density, when compared to those used in the traditional through holes technology.

Referring to FIGS. 1A to 1D, mounting electronic component such as passive component on a substrate by typical surface mounting technology is illustrated. As shown in the drawings, a substrate 10 formed with at least a paired solder pads 12 thereon is covered by a solder resist layer 13 and the solder resist layer 13 is formed with a plurality of openings 130 for partially exposing the corresponding at least a paired solder pads 12. A screen plate 17 with apertures 170 that correspond in position to the solder pads 12 is used to be attached onto the substrate 10, as shown in FIG. 1A, for purpose of screen printing, the apertures 170 of the screen plate 17 are of a rectangle shape in correspondence with the shape of the solder pads 12 (FIG. 1B shows a top view according to FIG. 1A). It thus allows a tin paste 14 to be coated, as shown in FIG. 1C, on each of the solder pads 12 by screen printing via the apertures 170 in corresponding with the openings 130. The screen plate 17 is removed from the substrate 10 subsequent to the formation of the tin paste 14. Then as shown in FIG. 1D, at least a passive component 15 is mounted on the substrate 10 in a manner that the conductive terminals of the passive component 15 are attached to the tin paste 14. It thus enables the passive component 15 to be electrically connect to the solder resist layer 13 of the substrate 10 by subjecting the tin paste 14 to reflow.

However, in the reflow process, the passive component 15 tends to shift in position or tilt in level due to uneven flow of the tin paste, namely, a tombstoning effect. Furthermore, since electronic products nowadays have a common trend of being lighter in weight and smaller in size, sizes of solder resist layers and passive components are getting smaller and smaller as demanded, whereby how to precisely mount passive components on the substrate without issues of shifting in position and tilting in level, are seriously desired.

In order to solve the foregoing problems, U.S. Pat. No. 5,311,405 discloses a method and apparatus for aligning and attaching a surface mount component. As shown in FIGS. 2A and 2B, the features of U.S. Pat. No. 5,311,405 are illustrated. Referring to the drawings, a plurality of tri-oval solder pads 22 are laid on a solder pad mount area 21 of a substrate 20, allowing each of the solder pads 22to have a pre-set electronic component mount area 221 for mounting electronic component. And then in a reflow process, solder paste 23 on the solder pad 22 will liquefy and flow toward an arched end 222 of the solder pad 22 in the direction as indicated by arrow A. Accordingly, when an electronic component 24 are not aligned with a desired position of the electronic component mount areas 221, the conductive terminals 241 of the electronic component 24 is allowed to be driven to shift to aligned with the desired position of the pre-set electronic component mount areas 221 by the flow of the liquefied solder paste 23 during the reflow process, as indicated by arrow B. Accordingly, the electronic component 24 is able to be mounted at a desired position on the corresponding electronic component mount areas 221.

In addition, U.S. Pat. No. 6,566,611 proposes an “Anti-tombstoning Structures and Methods of Manufacture” as shown in FIGS. 3A and 3B. The U.S. Pat. No. 6,566,611 patent provides a structure that includes a substrate 30 having a paired solder pads 31, a conductive material 32 formed on the paired solder pads 31, and an electronic component 33 attached on the conductive material 32. Each of the solder pads 31 is formed with a recess 312 in a manner that the openings of the recesses 312 face opposite direction. Due to formation of the recesses 312, during reflow to the conductive material 32, surface tension of the conductive material 32 will centralize toward the openings of the recesses 312. As the centralization of the surface tension of the conductive material 32 exert force to the opposite directions, the electronic component 33 can be prevented from shifting in position or tilting in level.

However, both the above-mentioned prior arts have the drawback that specific shape of the solder pad is required to be formed, resulting in increase of fabrication cost as well as complexity of fabrication process.

### SUMMARY OF THE INVENTION

In view of the disadvantages of the prior art mentioned above, it is a primary objective of the present invention to provide a semiconductor device having electronic components and its fabrication method, that are capable of preventing the electronic components from shifting in position or tilting in level with respect to the substrate or the solder pads which the electronic components are to be mounted, during the surface mounting process.

It is another objective of the present invention to provide a semiconductor device having electronic components and its fabrication method, which are simple in fabrication process and thus lower in fabrication cost when compared to the prior art.

To achieve the aforementioned and other objectives, a fabrication method of semiconductor device having electronic components is provided according to the present invention. The fabrication method comprises applying a conductive material on each one of at least a paired solder pads formed on a substrate to partially cover the paired solder pads with a recess formed in the conductive material on each one of the solder pads so as to expose a portion of each one of the solder pads and in a manner that the recesses on the solder pads are formed in position corresponding to each other; and mounting at least an electronic component having two opposing conductive terminals on the paired solder pads, with the two opposing conductive terminals of the electronic component introduced into the corresponding recesses of the conductive material, so as to electrically connect the electronic component to the paired solder pads via the conductive material after reflow.

The conductive material can be formed on the paired solder pads by means of screen printing. The screen plate to be used in the screen printing process has at least a paired apertures formed in position corresponding to the paired solder pads, and each one of the paired apertures has a notched portion for forming the recess in the conductive material. The notched portion of the paired apertures are formed in position corresponding to each other.

By means of foregoing fabrication method, the present invention further discloses a semiconductor device having at least a electronic component. The semiconductor device comprises: a substrate; at least a paired solder pads formed on the substrate; a conductive material applied on the at least a paired solder pads with a recess formed in the conductive material on each one of the at least a paired solder pads, so as to expose a portion of each one of the at least a paired solder pads, wherein the recesses formed on the at least a paired solder pads are corresponding in position to each other; and at least an electronic component having two opposing conductive terminals and mounted on the at least a paired solder pads, wherein the two conductive terminals of the electronic component are respectively introduced into the corresponding recesses of the conductive material, so as for the electronic component to be electrically connect to the at least a paired solder pads via the conductive material.

The semiconductor device having electronic components and its fabrication method according to the present invention comprising applying a screen plate habing at least a paired apertures on a substrate having at least a paired solder pads and subjecting a conductive material applied on the at least a paired solder pads to screen printing, wherein each one of the paired apertures formed on the screen plate to be used in the screen printing process have a notched portion; the conductive material has recesses corresponding in position to each other; and at least an electronic component is formed with two opposing conductive terminals on the at least a paired solder pads, in a manner that the two opposing conductive terminals are introduced into the corresponding recesses of the conductive material so as for the electronic component to be electrically connected to the at least a paired solder pads via the conductive material by reflow. Compared with the prior art, the conductive material according to the present invention has recesses for mounting and securing an electronic components, meanwhile, the electronic component is allowed to be electrically connected to the paired solder pads via the conductive material having recesses so as to prevent the electronic components from shifting in position during reflow. Furthermore, both terminals of the electronic component are not formed with conductive material underneath so as to prevent the electronic components from tilting in level resulted from the uniform applying of the conductive material. In addition, according to the present invention, there is no need of changing the shape of the solder pads, such that the present invention is simple in fabrication process and thus lower in fabrication cost when compared to the prior art.

### BRIEF DESCRIPTION OF DRAWINGS

The present invention can be more fully understood by reading the following detailed description of the preferred embodiments, with reference made to the accompanying drawings, wherein:

FIGS. 1A to 1D are diagrams for illustrating the process of mounting an electronic component, e.g. passive component, on a substrate by surface mounting technology;

FIGS. 2A and 2B, which are diagrams illustrating structure of solder pads according to claims of U.S. Pat. No. 5,311,405;

FIGS. 3A and 3B, which are diagrams illustrating structure of solder pads according to claims of U.S. Pat. No. 6,566,611; and

FIGS. 4A to 4D, which are diagrams illustrating a semiconductor device that has electronic component and its fabrication method according to the present invention.

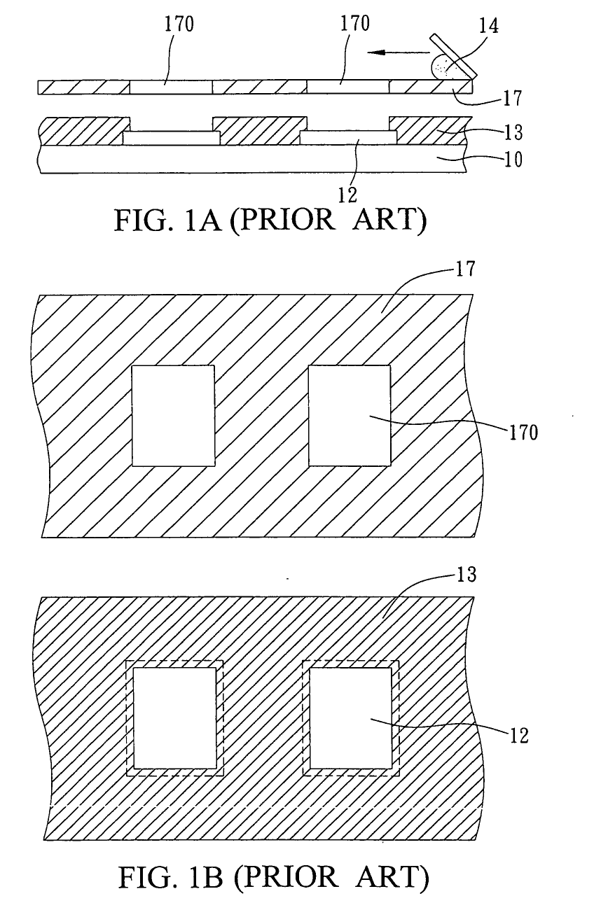

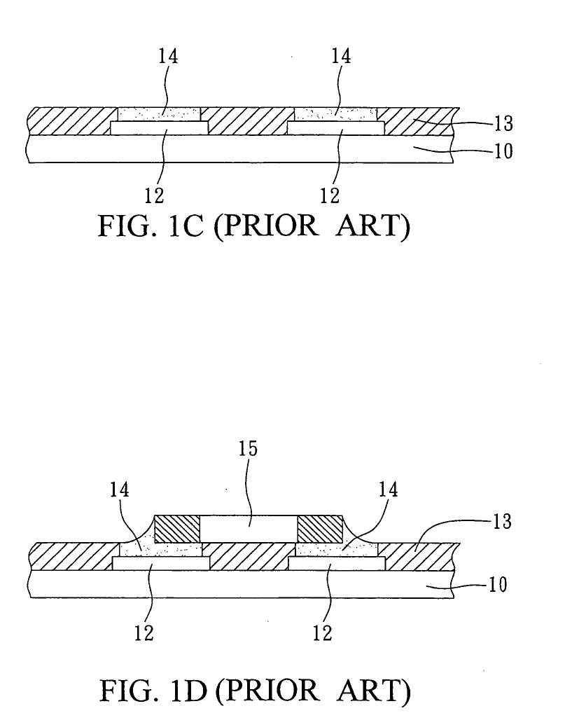

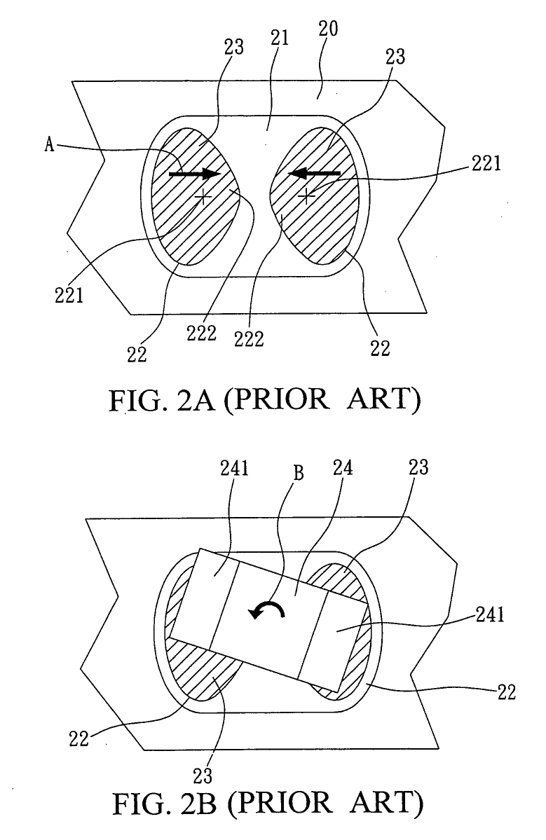

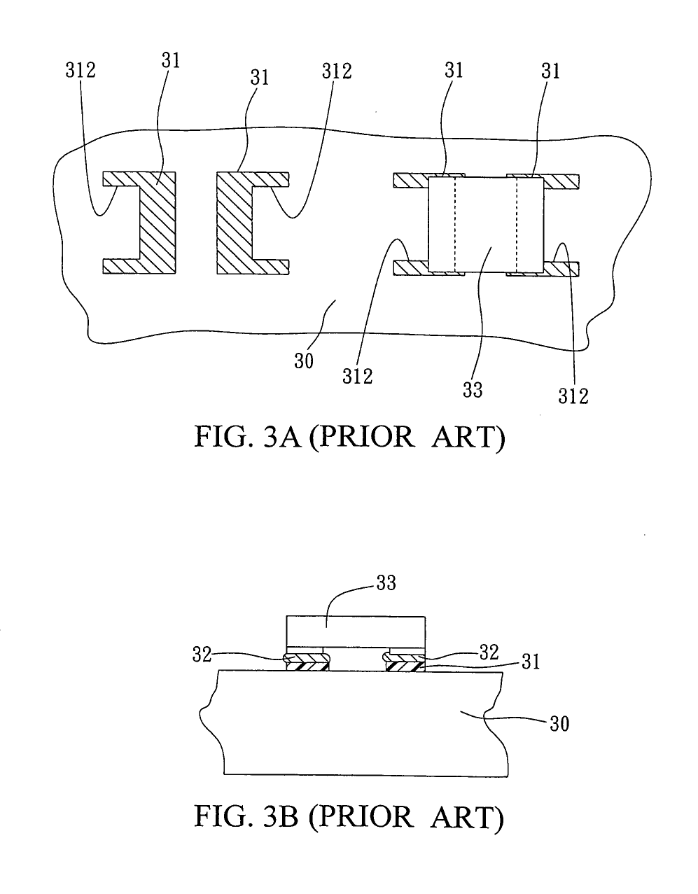

### DETAILED DESCRIPTION OF PREFERRED EMBODIMENTS

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

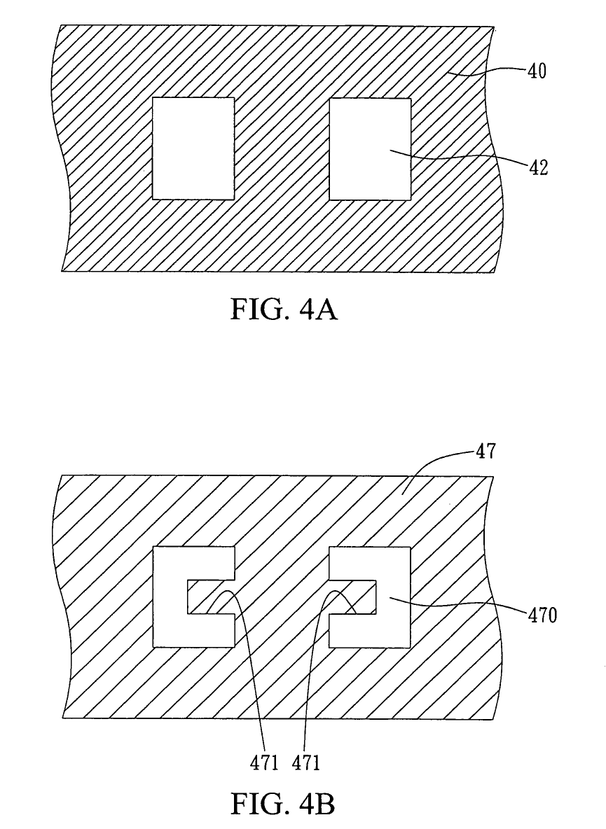

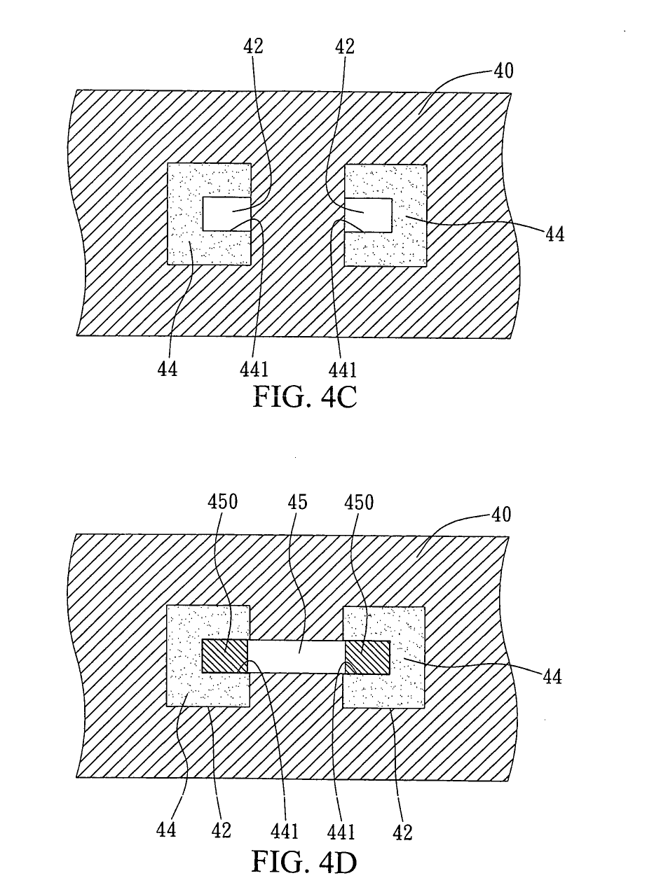

Referring now to FIGS. 4A to 4D, a fabrication method of a semiconductor device having at least an electronic components according to the present invention is illustrated.

As shown in FIG. 4A, prepare a substrate 40, the substrate 40 has at least a paired solder pads 42 on its surface.

The substrate 40 can be one of a group of packing board for chip packing, circuit board, printing circuit board, and etc., and there are a plurality of solder pads 42 laid on the substrate 40. In the present embodiment, the solder pads 42 are laid in pairs, the solder pads have similar area to each other and shape of solder pads is rectangle.

As shown in FIG. 4B, meanwhile, provide a screen plate 47, which has apertures 470 corresponding in position of the solder pads 42, and each pair of apertures 47 has a pair of notched portions 471 facing each other.

As shown in FIG. 4C, conductive material 44 is formed on the paired solder pads to partially cover the paired solder pads by making use of the screen plate 47 and screen printing technology, thus to have a pair of recesses 441 that are facing each other be formed on the conductive material 44. The conductive material can be made of, e.g., solder material.

As shown in FIG. 4D, mount an electronic component 45 that has a conductive terminal 450 at each end on the paired solder pads 42, and have the conductive terminals 450 at both ends of the electronic component 45 be contained inside the recesses 441 of the conductive material 44, thus in a subsequent reflow process, the conductive terminals 450 at both ends of the electronic component 45 are soldered onto the paired solder pads 42 with the conductive material 44 around the conductive terminals 450, and meantime the electronic component 45 is electrically connecting to the paired solder pads 42. The electronic component 45 is an passive component, e.g. an passive component of 0201 type or even smaller chip.

In view of the above, the semiconductor device that has electronic component of the present invention comprises: a substrate 40; at least a paired solder pads 42 formed on surface of the substrate 40; conductive material 44 formed on the paired solder pads 42 to partially cover the paired solder pads 42, the conductive material 44 on the paired solder pads 42 has a pair of recesses 441 that are facing each other; an electronic component 45 that has a conductive terminal 450 at each end, the electronic component 45 is mounted on the paired solder pads 42 and both ends of the electronic component are contained inside the pair of recesses 441 of the conductive material 44, thus to have the electronic component 45 electrically connect to the paired solder pads via the conductive material 44.

Accordingly, The semiconductor device having electronic components and its fabrication method according to the present invention comprising applying a screen plate having at least a paired apertures on a substrate having at least a paired solder pads and subjecting a conductive material applied on the at least a paired solder pads to screen printing, wherein each one of the paired apertures formed on the screen plate to be used in the screen printing process have a notched portion; the conductive material has recesses corresponding in position to each other; and at least an electronic component is formed with two opposing conductive terminals on the at least a paired solder pads, in a manner that the two opposing conductive terminals are introduced into the corresponding recesses of the conductive material so as for the electronic component to be electrically connected to the at least a paired solder pads via the conductive material by reflow. Compared with the prior art, the conductive material according to the present invention has recesses for mounting and securing an electronic components, meanwhile, the electronic component is allowed to be electrically connected to the paired solder pads via the conductive material having recesses so as to prevent the electronic components from shifting in position during reflow. Furthermore, both terminals of the electronic component are not formed with conductive material underneath so as to prevent the electronic components from tilting in level resulted from the uniform applying of the conductive material. In addition, according to the present invention, there is no need of changing the shape of the solder pads, such that the present invention is simple in fabrication process and thus lower in fabrication cost when compared to the prior art.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A fabrication method of a semiconductor device having electronic components, comprising the steps of:
applying a conductive material on each one of at least a paired solder pads arranged on a substrate, with a recess formed in the conductive material on each one of the at least a paired solder pads, so as to expose a portion of each one of the at least a paired solder pads, wherein the recesses on the at least a paired solder pads are formed in position corresponding to each other; and
mounting at least an electronic component having two opposing conductive terminals on the at least a paired solder pads, in a manner that the two opposing conductive terminals are introduced into the corresponding recesses of the conductive material so as for the electronic component to be electrically connected to the at least a paired solder pads via the conductive material.

2. The fabrication method of a semiconductor device having electronic component of claim 1, wherein the substrate is one of a packing board for use in a semiconductor package, a circuit board, and a printing circuit board.

3. The fabrication method of a semiconductor device having electronic components of claim 1, wherein the electronic component is a passive component.

4. The fabrication method of a semiconductor device having electronic components of claim 1, wherein the shape of each one of the at least a paired solder pads is rectangle.

5. The fabrication method of a semiconductor device having electronic components of claim 1, wherein the conductive material is applied on the at least a paired solder pads by screen printing, such that a screen plate used for the screen printing is required to be formed with a plurality of paired apertures corresponding in position to the at least a paired solder pads, and each one of the paired apertures has a notched portion corresponding in position to that formed with another aperture of the paired ones.

6. The fabrication method of a semiconductor device having electronic components of claim 1, wherein the electronic component is electrically connected to the at least a paired solder pads via the conductive material by reflow.

7. A semiconductor device having at least an electronic component, comprising:
a substrate;
at least a paired solder pads formed on the substrate;
a conductive material applied on the at least a paired solder pads with a recess formed in the conductive material on each one of the at least a paired solder pads, so as to expose a portion of each one of the at least a paired solder pads, wherein the recesses formed on the at least a paired solder pads are corresponding in position to each other; and
at least an electronic component having two opposing conductive terminals and mounted on the at least a paired solder pads, wherein the two conductive terminals of the electronic component are respectively introduced into the corresponding recesses of the conductive material, so as for the electronic component to be electrically connect to the at least a paired solder pads via the conductive material.

8. The semiconductor device having at least an electronic component of claim 7, wherein the substrate is one of a packing board for use in a semiconductor package, a circuit board, and a printing circuit board.

9. The semiconductor device having at least an electronic component of claim 7, wherein the electronic component is a passive component.

10. The semiconductor device having at least an electronic component of claim 7, wherein the shape of each one of the at least a paired solder pads is rectangle.

11. The semiconductor device having at least an electronic component of claim 7, wherein the conductive material is applied on the at least a paired solder pads by screen printing, such that a screen plate used for the screen printing is required to be formed with a plurality of paired apertures corresponding in position to the at least a paired solder pads, and each one of the paired apertures has a notched portion corresponding in position to that formed with another aperture of the paired ones.

12. The semiconductor device having at least an electronic component of claim 7, wherein the electronic component is electrically connected to the at least a paired solder pads via the conductive material by reflow.
